(19) United States
(12) Patent Application Publication
(10) Pub. No.: US 2026/0143835 A1
(43) Pub. Date: May 21, 2026

(54) IMAGE SENSOR INCLUDING PIXEL REGION

(71) Applicant: SAMSUNG ELECTRONICS CO., LTD., Suwon-si (KR)

(72) Inventors: Hyungchae KIM, Suwon-si (KR); Kwanyoung OH, Suwon-si (KR); Kazunori KAKEHI, Suwon-si (KR)

(73) Assignee: SAMSUNG ELECTRONICS CO., LTD., Suwon-si (KR)

(21) Appl. No.: 19/394,475

(22) Filed: Nov. 19, 2025

(30) Foreign Application Priority Data
Nov. 20, 2024 (KR) 10-2024-0166608

(51) Int. Cl. H10F 39/00; H04N 25/78; H10F 39/18; H04N 25/40

(52) U.S. Cl. CPC H10F 39/8027; H04N 25/78; H10F 39/182; H10F 39/807; H04N 25/40

(57) ABSTRACT

An image sensor includes a first pixel region; and a second pixel region, in which the first pixel region includes: a first active region on a semiconductor substrate and extending in a first direction; a second active region on the semiconductor substrate, contacting the first active region, and extending in a second direction that is different from the first direction; and a first transistor that comprises a first gate structure, the first active region, and the second active region, in which the first gate structure comprises a first gate line on the first active region, a second gate line on the second active region, and a third gate line connecting the first gate line to the second gate line, in which at least a portion of the third gate line extends over a device isolation layer separating the first active region and the second active region from other active regions.

### CROSS-REFERENCE TO RELATED APPLICATION

This application is based on and claims priority under 35 U.S.C. § 119 to Korean Patent Application No. 10-2024-0166608, filed on November 20, 2024, in the Korean Intellectual Property Office, the disclosure of which is incorporated by reference herein in its entirety.

### BACKGROUND

The embodiments of the present disclosure are directed to an image sensor, and more particularly, to an image sensor including a pixel region where pixels are formed.

Image sensors that capture images and convert them into electrical signals are used not only in electronic devices for general consumers, such as digital cameras, mobile phone cameras, and portable camcorders, but also in cameras provided in vehicles, security systems, and robots.

As the number of two-dimensionally arranged pixels increases, and the size of each pixel decreases, various methods have been suggested to effectively form devices that are respectively arranged in the pixels and providing pixel circuits. Particularly, transistors using in existing fine pixels are difficult to fully utilize the active regions of the transistors, and are more vulnerable to the Short Channel Effect (SCE) as the channel length decreases.

### SUMMARY

The embodiments of the present disclosure provide an image sensor in which the noise of pixel signals is reduced.

Technical problems to be solved by the embodiments of the present disclosure are not limited to the above description, and other technical problems may be clearly understood by one of ordinary skill in the art from the descriptions provided hereinafter.

According to an aspect of the disclosure, an image sensor includes: a first pixel region; and a second pixel region, in which the first pixel region includes: a first active region on a semiconductor substrate and extending in a first direction; a second active region on the semiconductor substrate, contacting the first active region, and extending in a second direction that is different from the first direction; and a first transistor that comprises a first gate structure, the first active region, and the second active region, in which the first gate structure includes a first gate line on the first active region, a second gate line on the second active region, and a third gate line connecting the first gate line to the second gate line, and in which at least a portion of the third gate line is arranged to extend over a device isolation layer separating the first active region and the second active region from other active regions.

According to an aspect of the disclosure, an image sensor including a first pixel region; and a second pixel region, in which the first pixel region includes: a first active region and a second active region on a semiconductor substrate; a first active contact, a second active contact, and a third active contact each of which contacts at least one of the first active region and the second active region, a first transistor that comprises a first gate structure, the first active region, and the second active region, and a device isolation layer on the semiconductor substrate and separating the first active region and the second active region from other active regions, in which the first gate structure comprises a first gate line on the first active region, a second gate line on the second active region, and a third gate line connecting the first gate line to the second gate line, and in which at least a portion of the third gate line overlaps the device isolation layer in a first direction of the semiconductor substrate.

According to an aspect of the disclosure, an image sensor includes a pixel region, in which the pixel region includes: a first active region and a second active region on a semiconductor substrate, and a transistor comprising a gate structure, the first active region, and the second active region, in which the gate structure comprises a first gate line on the first active region, a second gate line on the second active region, and a third gate line connecting the first gate line to the second gate line, and in which a first channel of the transistor is on the first active region, and a second channel of the transistor is on the second active region.

### BRIEF DESCRIPTION OF THE DRAWINGS

Embodiments will be more clearly understood from the following detailed description taken in conjunction with the accompanying drawings in which:

FIG. 1 is a block diagram of an image sensor according to one or more embodiments;

FIGS. 2A to 2D are circuit diagrams of pixel groups included in a pixel array of FIG. 1 according to one or more embodiments;

FIG. 3 illustrates a pixel group included in an image sensor, according to one or more embodiments;

FIG. 4 is an enlarged view showing region A of FIG. 3 according to one or more embodiments;

FIG. 5 is a diagram for describing a current density in a second transistor in region A of FIG. 3 according to one or more embodiments;

FIGS. 6A and 6B are cross-sectional views of the image sensor, respectively taken along a line Ⅰ-Ⅰ’ and a line Ⅱ-Ⅱ’ of FIG. 4 according to one or more embodiments;

FIG. 7 is a diagram illustrating a pixel group included in an image sensor, according to one or more embodiments;

FIG. 8A is a diagram illustrating a pixel group included in an image sensor, according to one or more embodiments;

FIG. 8B is a cross-sectional view of the image sensor, taken along a line Ⅲ-Ⅲ’ of FIG. 8A according to one or more embodiments;

FIG. 9 is a diagram illustrating a pixel group included in an image sensor, according to one or more embodiments;

FIGS. 10 and 11 are diagrams illustrating pixel groups included in an image sensor, according to one or more embodiments; and

FIGS. 12 and 13 are diagrams illustrating pixel groups included in an image sensor, according to one or more embodiments.

### DETAILED DESCRIPTION OF THE EMBODIMENTS

Hereinafter, one or more embodiments are described in detail with reference to the attached drawings.

It will be understood that, although the terms first, second, third, fourth, etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of the disclosure.

It will be understood that when an element or layer is referred to as being “over,” “above,” “on,” “below,” “under,” “beneath,” “connected to” or “coupled to” another element or layer, it can be directly over, above, on, below, under, beneath, connected or coupled to the other element or layer or intervening elements or layers may be present. In contrast, when an element is referred to as being “directly over,” “directly above,” “directly on,” “directly below,” “directly under,” “directly beneath,” “directly connected to” or “directly coupled to” another element or layer, there are no intervening elements or layers present.

A layer may be described as having an upper surface and a lower surface. As understood by one of ordinary skill in the art, the surfaces of a layer may also be described as first and second surfaces, where a first surface may be one of the upper surface and the lower surface of the layer, and the second surface may be the other of the upper surface and the lower surface of the layer.

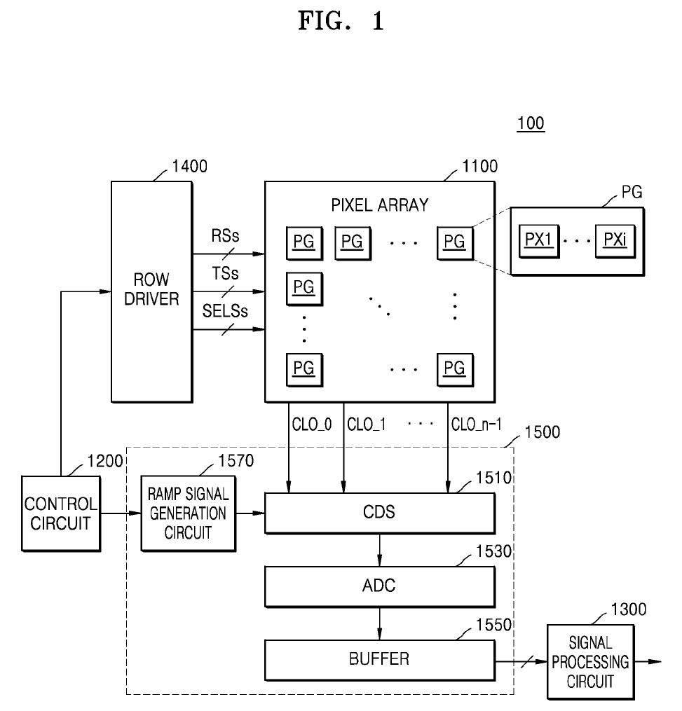

FIG. 1 is a block diagram of an image sensor 100 according to one or more embodiments.

Referring to FIG. 1, the image sensor 100 may include a pixel array 1100, a control circuit 1200, a signal processing circuit 1300, a row driver 1400, and a readout circuit 1500. The readout circuit 1500 may include a Correlated Double Sampler (CDS) 1510, an Analog-Digital Converter (ADC) 1530, and a buffer 1550.

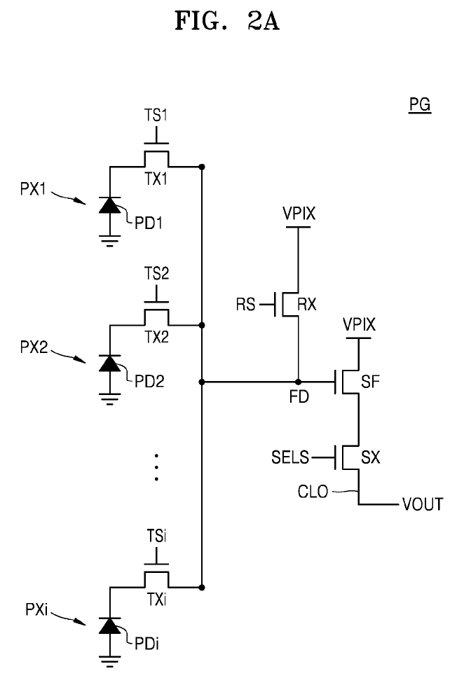

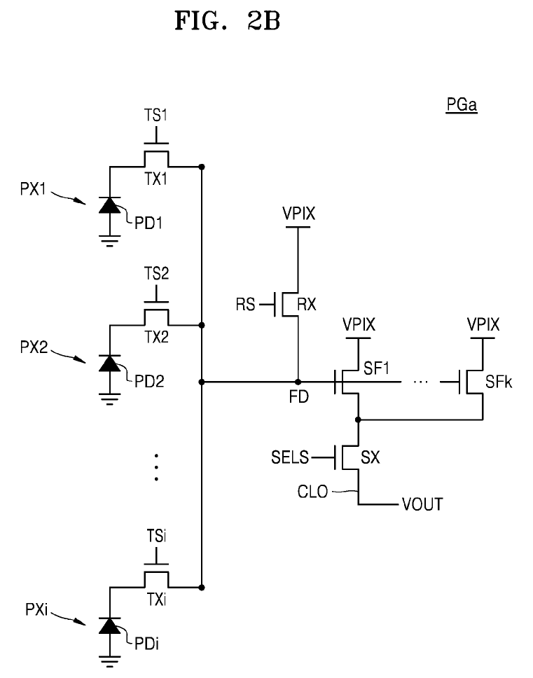

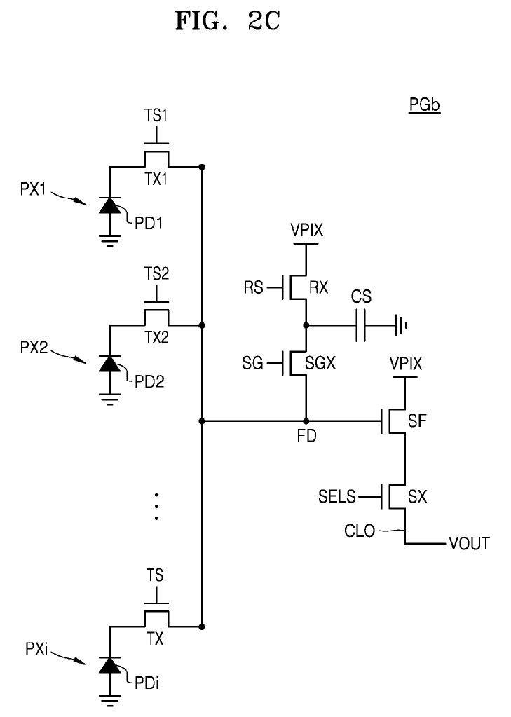

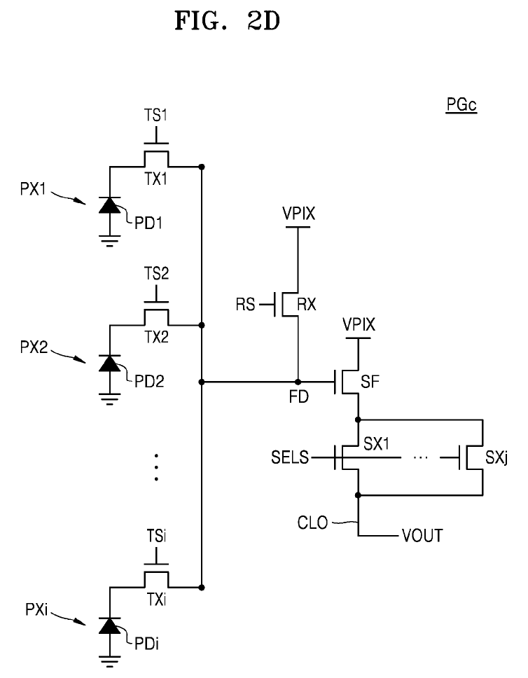

The pixel array 1100 may convert optical signals into electrical signals and include a plurality of pixel groups PG that are two-dimensionally arranged. Each pixel group PG may include a plurality of pixels, for example, a first pixel PX1 to an i^{th} pixel PXi (where, i is a natural number of at least two). The plurality of pixels PX1 to PXi included in the pixel array 1100 may generate pixel signals according to the intensity of detected light and may be implemented as photoelectric conversion devices, such as Charge Coupled Devices (CCDs) or Complementary Metal Oxide Semiconductors (CMOSs), or as various other types of photoelectric conversion devices. In one or more embodiments, the plurality of pixels PX1 to PXi included in one pixel group PG may share a floating diffusion region (e.g., a floating diffusion region FD of FIG. 2A) and also share a reset transistor RX, an amplifier transistor SF, and a selection transistor SX. A circuit configuration of the pixel group PG is described below with reference to FIGS. 2A to 2D. In one or more examples, a floating diffusion region of a pixel may be formed as an N+ implant in a semiconductor substrates, which enables the use of transistors such as a transfer resistor and a reset transistor.

The pixel array 1100 may include color filters to sense various colors, and each pixel group PG may sense their corresponding colors. For example, each pixel group PG may include its corresponding color filter among a red color filter, a green color filter, and a blue color filter. In one or more examples, each pixel group PG may include, for example, at least one of a yellow color filter, a cyan color filter, and a magenta color filter. For example, each pixel group PG may be configured to transmit light entirely in the visible light range.

In one or more embodiments, the pixel groups PG may include color filters arranged in a Bayer pattern, and for example, the pixel array 1100 may include a color filter array having a tetra pattern with a 2x2 matrix Bayer pattern, a nona pattern with a 3x3 matrix Bayer pattern, or a tetra-square pattern with a 4x4 matrix Bayer pattern.

Each pixel group PG may output a pixel signal to the CDS 1510 through its corresponding column output line among a first column output line CLO_0 to an n^{th} column output line CLO_n-1. The CDS 1510 may sample and hold the pixel signals provided from the pixel array 1100. The CDS 1510 may doubly sample a level of specific noise and a level according to the pixel signal and thus output a level corresponding to the difference therebetween. In one or more examples, the CDS 1510 may receive and compare ramp signals generated by a ramp signal generating circuit 1570 and output a comparison result.

The ADC 1530 may convert analog signals, which correspond to the levels received from the CDS 1510, into digital signals. The buffer 1550 may latch the digital signals, and the latched digital signals may be sequentially output to the signal processing circuit 1300 or may be output to the outside of the image sensor 100 as image data.

The control circuit 1200 may control the row driver 1400 to enable the pixel array 1100 to accumulate photocharges by absorbing light or temporarily store the accumulated photocharges and output electrical signals according to the stored photocharges to the outside of the pixel array 1100. In addition, the control circuit 1200 may control the readout circuit 1500 to measure the levels of the pixel signals provided by the pixel array 1100. As understood by one of ordinary skill in the art, a photocharge may be a photoelectric charge generated by individual pixels when exposed to light, which are then used to form an image. The photocharges may be proportional to an intensity of the light hitting each pixel.

The row driver 1400 may generate signals RSs, TSs, and SELSs for controlling the pixel array 1100 and provide the signals RSs, TSs, and SELSs to the plurality of pixels PX. The row driver 1400 may determine the activation timings and inactivation timings of the reset control signals RSs, transmission control signals TSs, and selection signals SELSs provided to the plurality of pixels PX.

The signal processing circuit 1300 may perform signal processing on the signals output from the buffer 1550. In one or more embodiments, the signal processing circuit 1300 may perform image processing operations including re-mosaic processing performed on the data received from the readout circuit 1500. In one or more embodiments, the signal processing circuit 1300 may also perform signal processing, such as noise reduction, gain adjustment, waveform shaping, interpolation, white balance adjustment, gamma correction, and edge enhancement. In one or more embodiments, the signal processing circuit 1300 may be included in a processor outside the image sensor 100.

FIGS. 2A to 2D are circuit diagrams of pixel groups PG included in the pixel array 1100 of FIG. 1.

Referring to FIG. 2A, in one or more examples, the pixel group PG may include a plurality of pixels PX1 to PXi including a same color filter. In one or more embodiments, the pixels PX1 to PXi included in a single pixel group PG may share a floating diffusion region FD as well as a reset transistor RX, an amplifier transistor SF, and a selection transistor SX. However, the circuit diagram of the pixel group PG shown in FIG. 2A is only an example, and each of the pixels PX1 to PXi may include a floating diffusion region FD, or only some of the pixels PX1 to PXi may share a floating diffusion region FD.

The pixel group PG may include a plurality of photoelectric conversion devices, for example, a first photoelectric conversion device PD1 to an i^{th} photoelectric conversion device PDi (where, i is a natural number of at least two), and a plurality of transmission transistors TX1 to TXi. Each of the pixels PX1 to PXi may include its corresponding photoelectric conversion device (e.g., one of the first photoelectric conversion device PD1 to the i^{th} photoelectric conversion device PDi) and its corresponding transmission transistor (e.g., one of the transmission transistors TX1 to TXi). Each of the photoelectric conversion devices PD1 to PDi may generate photocharges that vary according to the intensity of light. For example, each of the photoelectric conversion devices PD1 to PDi may be a P-N junction diode and generate photocharges (e.g., electrons that are negative charges and holes that are positive charges), in proportion to the amount of incident light. Each of the photoelectric conversion devices PD1 to PDi may be an example of a photoelectric conversion device and may be at least one of a phototransistor, a photo gate, a pinned photodiode (PPD), and a combination thereof.

Each of the transmission transistors TX1 to TXi may transmit the generated photocharges to the floating diffusion region FD according to a transmission control signal (e.g., a corresponding one of transmission control signals TS1 to TSi). When each of the transmission transistors TX1 to TXi is turned on, the photocharges generated by each of the photoelectric conversion devices PD1 to PD4 included in the pixel group PG may be transmitted to a single floating diffusion region FD and accumulated and stored therein.

The reset transistor RX may periodically reset the charges accumulated in the floating diffusion region FD. One end of the reset transistor RX may be connected to the floating diffusion region FD, and the other end may be connected to a power voltage VPIX. When the reset transistor RX is turned on in response to the reset control signal RS, the charges accumulated in the floating diffusion region FD may be discharged such that the floating diffusion region FD may be reset.

Depending on the amount of photocharges accumulated in the floating diffusion region FD, the amplifier transistor SF may be controlled. As a buffer amplifier, the amplifier transistor SF may buffer signals according to the charges that are charged to the floating diffusion region FD and may operate as a source follower. The amplifier transistor SF may amplify a potential change in the floating diffusion region FD and output the amplified potential change to a column output line CLO (e.g., one of the column output lines CLO_0 to CLO_n-1) as a pixel signal VOUT. In response to the selection signal SELS, the selection transistor SX may output the pixel signal VOUT to the CDS (the CDS 1510 of FIG. 1) through the column output line CLO.

Referring to FIG. 2B, a pixel group PGa may include a plurality of photoelectric conversion devices PD1 to PDi, a plurality of transmission transistors TX1 to TXi, a reset transistor RX, and a selection transistor SX and also include a plurality of amplifier transistors, for example, a first amplifier transistor SF1 to a k^{th} amplifier transistor SFk (where, k is a natural number of at least two). A power voltage VPIX may be applied to one end of the first amplifier transistor SF1 to the k^{th} amplifier transistor SFk, and the other end may be connected to the selection transistor SX. The first amplifier transistor SF1 to the k^{th} amplifier transistor SFk may simultaneously operate and generate pixel signals VOUT according to the voltage at the floating diffusion region FD. Because the first amplifier transistor SF1 to the k^{th} amplifier transistor SFk in the pixel group PGa operate as a single amplifier transistor, the first amplifier transistor SF1 to the k^{th} amplifier transistor SFk may stably generate the pixel signals VOUT.

Referring to FIG. 2C, a pixel group PGb may include a plurality of photoelectric conversion devices PD1 to PDi, a plurality of transmission transistors TX1 to TXi, a reset transistor RX, an amplifier transistor SF, and a selection transistor SX. In addition, the pixel transistor PGb may include a storage control transistor SGX. The pixel group PGb may further include a capacitor CS having one end connected between the storage control transistor SGX and the reset transistor RX, but is not limited thereto.

The reset transistor RX may reset the floating diffusion region FD (e.g., reset the floating diffusion region FD to the level of the power voltage VPIX) according to a reset control signal RS provided from the row driver (e.g., the row driver 140 of FIG. 1). In one or more examples, the reset transistor RX may reset the capacitor CS (e.g., reset the capacitor CS to the level of the power voltage VPIX) according to the reset control signal RS. In other words, the reset transistor RX may be turned on in response to the reset control signal RS applied to a gate of the reset transistor RX and may reset the floating diffusion region FD or the capacitor CS based on the power voltage VPIX. For example, as the storage control transistor SGX is turned on together with the reset transistor RX in response to a storage control signal SG transmitted to a gate of the storage control transistor SGX, the power voltage VPIX may be applied to the floating diffusion region FD, and thus, the floating diffusion region FD may be reset.

The capacitor CS may be a passive element with a fixed or variable capacitance or may be a capacitor, which is formed by or connected to a source/drain of the storage control transistor SGX, or a parasitic capacitor, which is formed by another pixel group that may be connected to the source/drain of the storage control transistor SGX.

Because the photoelectric conversion devices PD1 to PDi generate charges based on light intensity, the amount of charges generated by the photoelectric conversion devices PD1 to PDi may vary depending on the image capturing environment (e.g., low luminance or high luminance). For example, in a high-luminance environment, the amount of charges generated by the first photoelectric conversion device PD1 may reach the full well capacity (FWC), but may not reach the FWC in a low-luminance environment.

The charges accumulated in the floating diffusion region FD may be converted into the voltage at the floating diffusion region FD. A conversion gain (e.g., the unit of the conversion gain may be, for example, uV/e) may be determined by the capacitance in the floating diffusion region FD and may be inversely proportional to the value of the capacitance. When the capacitance in the first floating diffusion region FD increases, the conversion gain may decrease, and the capacitance decreases, the conversion gain may increase.

The storage control transistor SGX may be turned on or off based on the storage control signal SG transmitted to the gate of the storage control transistor SGX, and when the storage control transistor SGX is turned on, the capacitor CS may be connected to the floating diffusion region FD, and the floating diffusion region FD may have parasitic capacitance and capacitance provided by the capacitor CS such that the total capacitance may increase.

The conversion gain when the storage control transistor SGX is off may be greater than the conversion gain when the storage control transistor SGX is on. The off state of the storage control transistor SGX may be referred to as a High Conversion Gain (HCG) mode, and the on state of the storage control transistor SGX may be referred to as a Low Conversion Gain (LCG) mode. In the HCG mode, each electron of light captured by a pixel may result in a larger voltage change, leading to increased sensitivity and reduced readout noise, which is beneficial for low-light conditions. In the LCG mode, each pixel reduces sensitivity to light to prioritize wider dynamic range, which is more suitable for bright scenes.

Thus, the pixel group PG may operate in one of the HCG mode and the LCG mode, depending on whether the storage control transistor SGX is on or off. In a low-luminance environment, the pixel group PG may operate in the HCG mode, and the low-light detection performance of the image sensor (e.g., the image sensor 100 of FIG. 1) may be improved. On the contrary, in a high-luminance environment, pixel group PG may operate in the LCG mode, and the floating diffusion region FD of the pixel group PG has great capacitance; thus, the FWC may increase. Therefore, the high-light detection performance of the image sensor 100 may be enhanced. In addition, the image sensor 100 may provide a dual conversion gain and sense light in both a low-light condition and a high-light condition, and thus, the dynamic range of the image sensor 100 may expand (or increase). The pixel group PGb of FIG. 2C that provides a dual conversion gain is an example, and the configuration thereof may vary.

Referring to FIG. 2D, a pixel group PGc may include a plurality of photoelectric conversion devices PD1 to PDi, a plurality of transmission transistors TX1 to TXi, a reset transistor RX, and an amplifier transistor SF and may also include a plurality of selection transistors, for example, a first selection transistor SX1 to a j^{th} selection transistor SXj (where, j is a natural number of at least two). One end of the first selection transistor SX1 to the j^{th} selection transistor SXj may be connected to the amplifier transistor SF, and the other end thereof may be connected to a column output line CLO. The first selection transistor SX1 to the j^{th} selection transistor SXj may be simultaneously controlled based on a selection signal SELS and output a pixel signal VOUT to the column output line CLO.

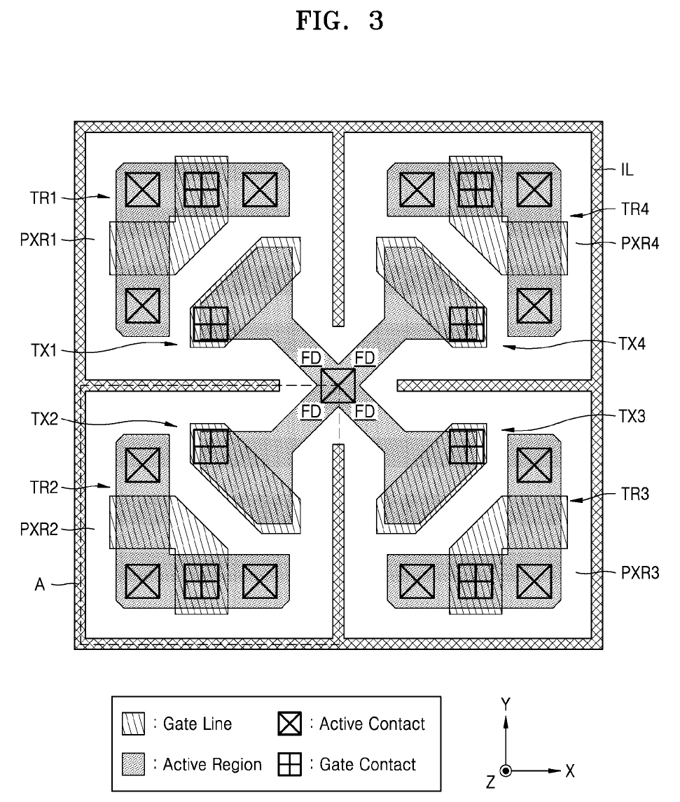

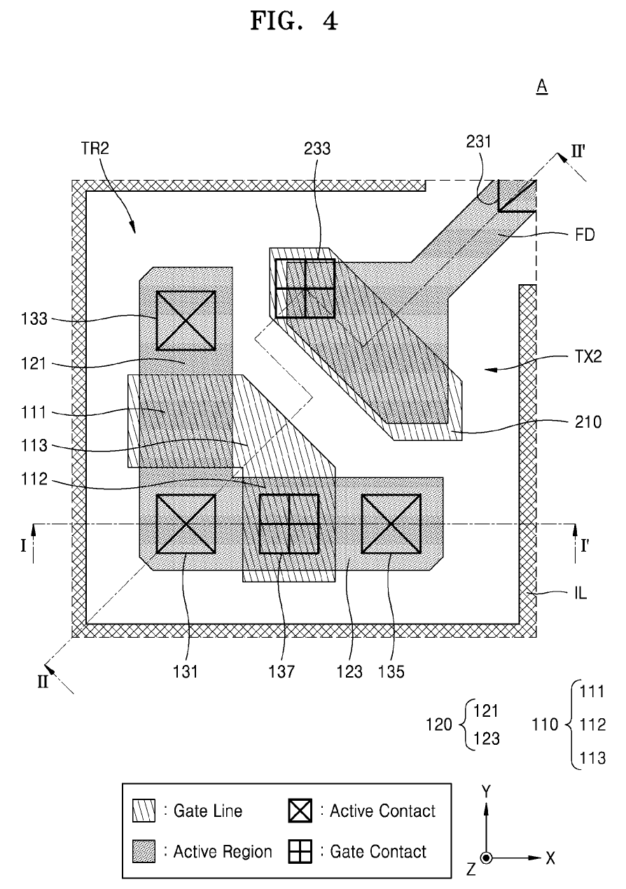

FIG. 3 illustrates a pixel group included in an image sensor, according to one or more embodiments. FIG. 4 is an enlarged view showing region A of FIG. 3.

Referring to FIG. 3, the pixel group may include four pixels. For example, the pixel group may include a first pixel to a fourth pixel, and the pixel group may include a first pixel region PXR1 to a fourth pixel region PXR4 which are arranged in two rows and two columns (2x2) along the X-axis direction and the Y-axis direction. A photodiode region included in each of the first pixel region PXR1 to the fourth pixel region PXR4 may be separated from each other by an isolation pattern IL and the pixel group may be distinguished from another pixel group by the isolation pattern IL. In this case, floating diffusion regions FD of the pixel group may be located at the center of the pixel group exposed by the isolation pattern IL.

In each of the first pixel region PXR1 to the fourth pixel region PXR4, a photoelectric conversion device may be formed, and a floating diffusion region FD, its corresponding transmission transistor among the first transmission transistor TX1 to the fourth transmission transistor TX4, and its corresponding transistor among the first transistor TR1 to the fourth transistor TR4 may be formed. Each of the first transistor TR1 to the fourth transistor TR4 may be one of the reset transistor RX, the amplifier transistor SF, the selection transistor SX, and the storage control transistor SGX described with reference to FIGS. 2A to 2D. For example, the first transistor TR1 may be the reset transistor RX, the second transistor TR2 may be the amplifier transistor SF, the third transistor TR3 may be the storage control transistor SGX, and the fourth transistor TR4 may be the selection transistor SX. However, as understood by one of ordinary skill in the art, the embodiments are not limited thereto, and the first transistor TR1 to the fourth transistor TR4 may vary. Although FIG. 3 illustrates that each of the pixel regions PXR1 to PXR4 are the same size, the embodiments are not limited to this configuration. For example, at least one of the pixel regions may be a different size than the other pixel regions.

Referring to FIGS. 3 and 4, in the second pixel region PXR2, a gate line structure 110 and an active region 120 of the second transistor TR2 may be formed. The active region 120 of the second transistor TR2 may include a first active region 121 extending in the first direction (e.g., the Y-axis direction) and a second active region 123 extending in the second direction (e.g., the X-axis direction). The first direction Y and the second direction X may be parallel to a main surface of a semiconductor substrate and perpendicular to each other.

The gate line structure 110 of the second transistor TR2 may include a first gate line 111, a second gate line 112, and a third gate line 113. The first gate line 111 may be formed to cross the first active region 121 on the first active region 121. The second gate line 112 may be formed to cross the second active region 123 on the second active region 123. The third gate line 113 may be formed to connect the first gate line 111 and the second gate line 112 to each other between the first gate line 111 and the second gate line 112.

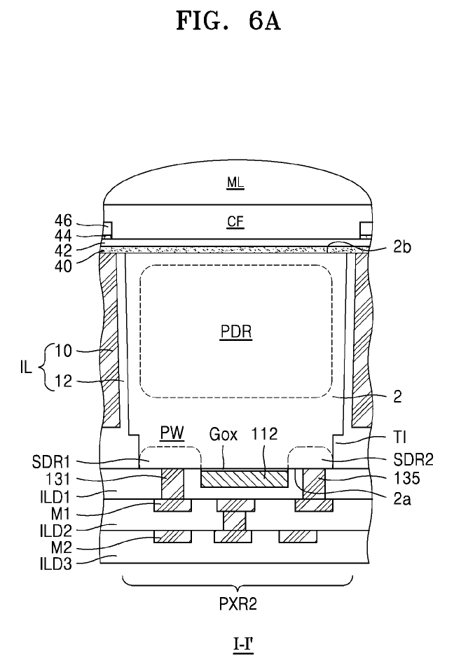

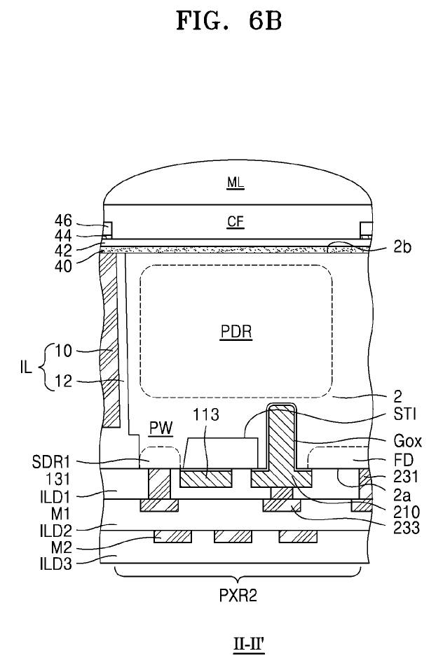

The third gate line 113 may be arranged to misalign with the first active region 121 and the second active region 123 in the vertical direction Z. For example, at least a portion of the third gate line 113 may overlap a device isolation layer (e.g., a device isolation layer STI of FIG. 6B) in the vertical direction Z. For example, at least a portion of the third gate line 113 may be formed to extend over the device isolation layer STI. The device isolation layer STI may electrically/physically separate the active region 120 of the second transistor TR2 from the active region (e.g., the floating diffusion region FD) of the second transmission transistor TX2.

In the second pixel region PXR2, a gate contact 137 contacting the gate structure 110 of the second transistor TR2 may be arranged. For example, the gate contact 137 may be arranged to contact one of the first gate line 111 and the second gate line 112. The gate contact 137 may electrically connect the gate structure 110 to a pattern of a wire layer.

As shown in FIG. 4, the second transistor TR2, which is formed as the amplifier transistor SF, includes the gate line structure 110 including the first gate line 111 to the third gate line 113, and thus, noise generated in the pixel signal output from the pixel group may be reduced. As the channel width of the second transistor TR2 increases because of the geometric characteristics of the gate line structure 110, the transconductance and gain of the second transistor TR2 may increase (e.g., the gain may be close to 1 in the voltage operation range of the floating diffusion region FD). Accordingly, noise in the pixel signal, which may be generated by the amplifier transistor SF (e.g., random noise or temporal noise) may be reduced.

Because the gate line structure 110 and the first active region 121 form a first channel of the second transistor TR2 and the gate line structure 110 and the second active region 123 form a second channel of the second transistor TR2 individually, currents may uniformly flow within the channels despite the reduction in the areas of the first active region 121 and the second active region 123 of the second transistor TR2, and because the channel length of the second transistor TR2 may increase, a short channel effect (SCE) may be prevented.

In the second pixel region PXR2, active contacts may be arranged to contact the active region 120 of the second transistor TR2. A first active contact 131 and a second active contact 133 may be arranged to contact the first active region 121, and the first active contact 131 and a third active contact 135 may be arranged to contact the second active region 123. For example, the first active contact 131 may be a drain contact, and the second active contact 133 and the third active contact 135 may each be a source contact. When the second transistor TR2 is the amplifier transistor SF of the pixel group, a power voltage (e.g., the power voltage VPIX of FIG. 2A) may be applied to the first active contact 131, and the second active contact 133 and the third active contact 135 may be connected to a column output line (e.g., the column output line CLO of FIG. 2A). In one or more examples, for example, the first active contact 131 may be a source contact connected to a source region of the second transistor TR2, and the second active contact 133 and the third active contact 135 may each be a drain contact connected to a drain region of the second transistor TR2.

The floating diffusion regions FD may be formed in the first pixel region PXR1 to the fourth pixel region PXR4, respectively. The floating diffusion region FD may be a region doped with first conductive-type impurities and a region where charges generated by photodiodes are accumulated. For example, the first conductive-type impurities may be N-type impurities.

The floating diffusion regions FD may be respectively connected to the first transmission transistor TX1 to the fourth transmission transistor TX4 and arranged adjacent to gate lines of the first transmission transistor TX1 to the fourth transmission transistor TX4. In one or more embodiments, the gate line of each of the first transmission transistor TX1 to the fourth transmission transistor TX4 may be formed as a single pattern. In one or more examples, in one or more embodiments, the gate line of each of the first transmission transistor TX1 to the fourth transmission transistor TX4 may be a buried gate line and may be formed by etching a semiconductor substrate to form a recess, and then forming a gate insulating pattern and a buried gate pattern in the recess.

The floating diffusion region FD may be formed to contact at least one active contact 231. The active contacts 231 of the floating diffusion regions FD may be connected to the patterns of the wire layer and may be electrically connected to the active regions or gate lines of some of the first transistor TR1 to the fourth transistor TR4. For example, when the second transistor TR2 is the amplifier transistor SF, the active contact 231 of the floating diffusion region FD may be electrically connected to the gate contact 137 of the second transistor TR2 through the patterns of the wire layer.

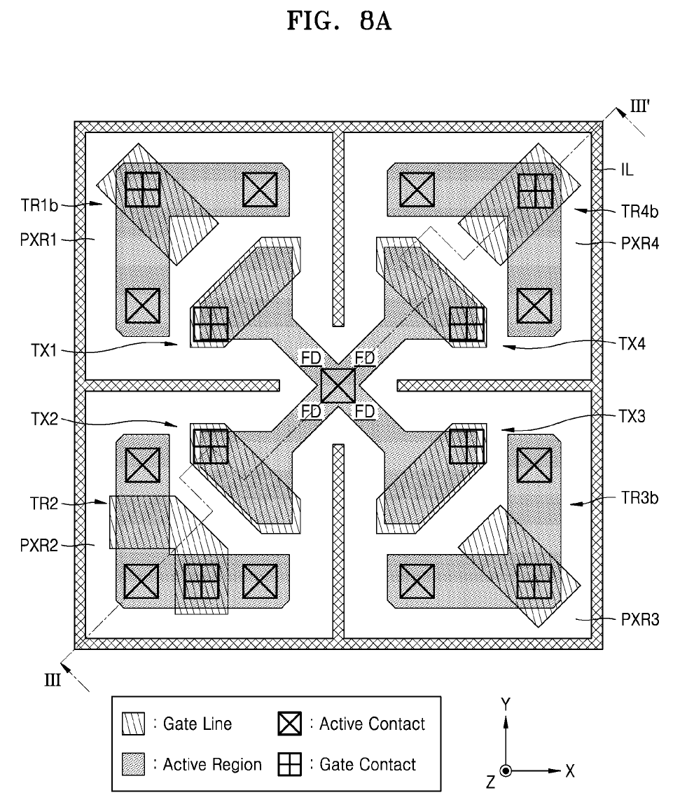

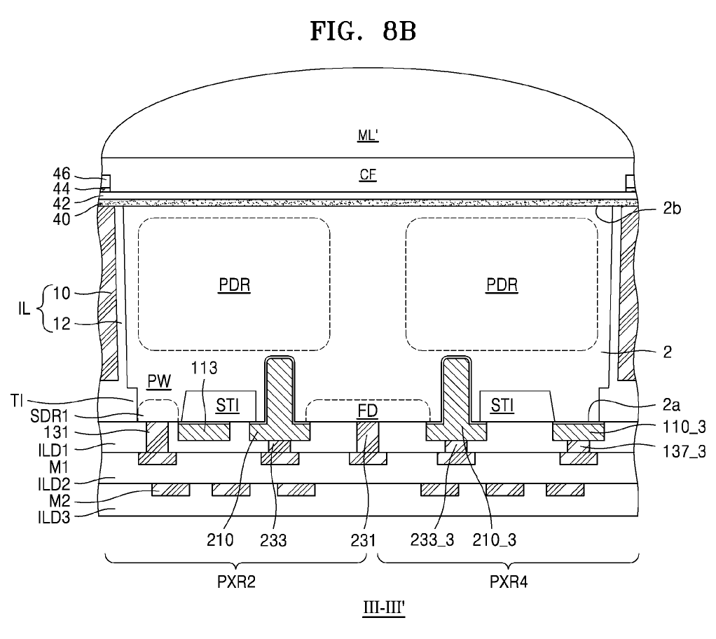

Referring back to FIG. 3, the description regarding the shape of the second transistor TR2, provided with reference to FIG. 4, may be similarly applied to the first transistor TR1, the third transistor TR3, and the fourth transistor TR4. For example, each of the first transistor TR1, the fourth transistor TR4, and the third transistor TR3 may have a shape formed as the second transistor TR2 is vertically, horizontally, or both vertically and horizontally inverted. However, the embodiments of the present disclosure are not limited thereto, and some of the first transmission transistor TX1 to the fourth transmission transistor TX4 may have shapes that are different from those of the others, as described below with reference to FIGS. 8A and 8B.

The floating diffusion region FD may be arranged at the center of the pixel group, each of the first pixel to the fourth pixel of the pixel group may share the floating diffusion region FD, and the floating diffusion region FD may be formed across the first pixel region PXR1 to the fourth pixel region PXR4. However, the shape and/or area of the floating diffusion region FD is not limited to that shown in FIG. 3 and may be variously modified according to embodiments.

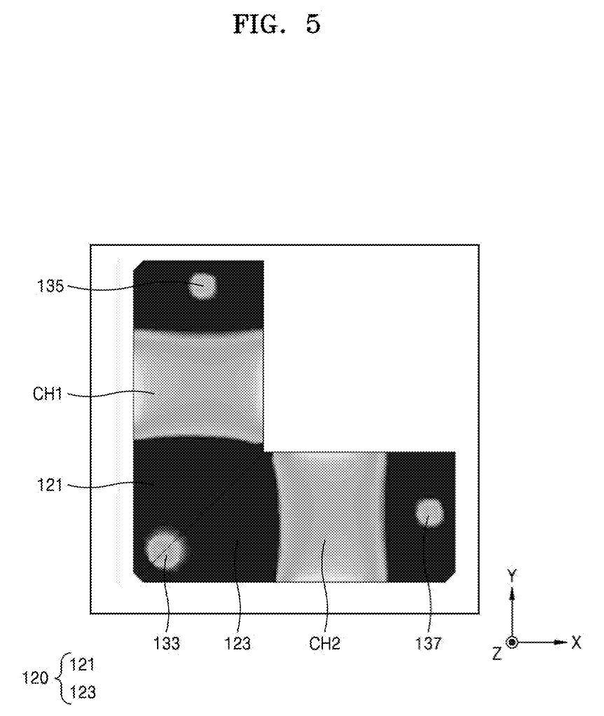

FIG. 5 is a diagram for describing a current density in a second transistor in region A of FIG. 3.

Referring to FIGS. 4 and 5, the second transistor TR2 may include the first gate line 111 and the second gate line 112, wherein the first gate line 111 is formed to cross the first active region 121 extending in the first direction Y and the second gate line 112 is formed to cross the second active region 123 extending in the second direction X. A first channel CH1 may be formed in the first active region 121 by the first gate line 111, a second channel CH2 may be formed in the second active region 123 by the second gate line 112, and the first channel CH1 and the second channel CH2 may be independently formed. Therefore, the channel length of the second transistor TR2 may increase, and although the areas of the first active region 121 and the second active region 123 of the second transistor TR2 are reduced, currents may uniformly flow in the first channel CH1 and the second channel CH2.

The second active contact 133 may be electrically connected to the third active contact 135 through the patterns of the wire layer. When the second transistor TR2 operates as an amplifier transistor (e.g., the amplifier transistor SF of FIG. 2A), the second transistor TR2 may substantially operate as if two amplifier transistors are connected in a parallel structure; that is, a dual-finger amplifier transistor may be implemented. The amplifier transistor SF may be more sensitive to inherent noise of transistor devices than other transistors of the pixel group, for example, a transmission transistor, a reset transistor, and a selection transistor, and the noise generated by the amplifier transistor SF may affect the pixel signal (e.g., the pixel signal VOUT of FIG. 2A), resulting in degradation in image quality. Therefore, the image sensor of the present disclosure includes the amplifier transistor SF that includes the gate structure 110 including the first gate line 111, the second gate line 112, and the third gate line 113, and thus, the pixel signal VOUT with improved noise characteristics may be generated, and the linearity of the current-voltage graph of the amplifier transistor SF may be improved.

FIGS. 6A and 6B are cross-sectional views of the image sensor, respectively taken along a line Ⅰ-Ⅰ’ and a line Ⅱ-Ⅱ’ of FIG. 4.

Referring to FIGS. 4, 6A, and 6B, the image sensor (e.g., the image sensor 100 of FIG. 1) of the present disclosure includes the semiconductor substrate 2. The semiconductor substrate 2 may include a plurality of pixel groups (e.g., the pixel groups PG of FIG. 1) that are two-dimensionally arranged in the first direction Y and the second direction X. FIGS. 6A and 6B illustrate a second pixel region PXR2 included in one pixel group PG.

The semiconductor substrate 2 may include a first surface 2a and a second surface 2b that are opposite to each other. Light may be incident to the semiconductor substrate 2 through the second surface 2b. The semiconductor substrate 2 may be a single crystalline wafer or an epitaxial layer including silicon (Si) and/or germanium (Ge), or a Silicon on Insulator (SOI) substrate. The semiconductor substrate 2 may be doped with second conductive-type impurities. The second conductive type may be, for example, P type. The second conductive-type impurities may be, for example, boron (B).

In the semiconductor substrate 2, an isolation pattern IL may be arranged, the isolation pattern IL separating a photodiode region included in each of a plurality of pixel regions (e.g., the first pixel region PXR1 to the fourth pixel region PXR4 of FIG. 3) and pixel groups from each other and defining the same. For example, the isolation pattern IL may be structured or designed to prevent electrical crosstalk or interference between neighboring pixels to ensure each pixel functions independently, thereby improving accurate and noise-free image capture. The isolation pattern IL may have a mesh shape in a plan view. The isolation pattern IL may be deep trench isolation. However, as understood by one of ordinary skill in the art, the embodiments are not limited to this configuration. For example, the isolation pattern may be shallow trench isolation, or any other suitable structure known to one of ordinary skill in the art.

In one or more embodiments, the isolation pattern IL may include an isolation conductive pattern 10, and an isolation insulating pattern 12. However, one or more embodiments are not limited thereto, and the isolation pattern IL may not include the isolation conductive pattern 10.

The isolation conductive pattern 10 may be spaced apart from the semiconductor substrate 2. The isolation conductive pattern 10 may include a conductive material with a refractive index that is different from that of the semiconductor substrate 2. For example, the isolation conductive pattern 10 may include polysilicon or metal doped with impurities. In one or more embodiments, as a lower voltage (e.g., a negative voltage) may be applied to the isolation conductive pattern 10 compared to a photoelectric transformation portion PDR, the energy barrier between the isolation conductive pattern 10 and the photoelectric transformation portion PDR may increase, thereby decreasing dark currents. Accordingly, the reliability of the image sensor may be improved.

The isolation insulating pattern 12 may be arranged between the isolation conductive pattern 10 and the semiconductor substrate 2, and a device isolation layer TI may be arranged under the isolation conductive pattern 10. The isolation insulating pattern 12 may include insulating materials having refractive indices that are different from that of the semiconductor substrate 2. For example, the isolation insulating pattern 12 may include silicon oxide.

The isolation pattern IL may penetrate the semiconductor substrate 2. In one or more embodiments, the isolation pattern IL may have the cross-sectional width decreasing from the first surface 2a to the second surface 2b. In one or more embodiments, the isolation pattern IL may be formed from the second surface 2b to the first surface 2a and may have the cross-sectional width decreasing from the second surface 2b to the first surface 2a. In one or more embodiments, the isolation pattern IL may penetrate only part of the semiconductor substrate 2.

The substrate 2 may include a photodiode region in which a photodiode is formed and defined by the isolation pattern IL, and the photodiode region may include the photoelectric conversion unit PDR. The photoelectric transformation portion PDR may be arranged within the semiconductor substrate 2. A well region PW may be arranged between the photoelectric transformation portion PDR and the first surface 2a. The well region PW may be doped with, for example, second conductive-type impurities doped in the semiconductor substrate 2. The concentration of the second conductive-type impurities in the well region PW may be the same as or greater than the concentration of the impurities in the semiconductor substrate 2.

The photoelectric transformation portion PDR may be doped with first conductive-type impurities that are different from the second conductive-type impurities. For example, the photoelectric transformation portion PDR may be doped with N-type impurities, for example, phosphorus (P) or arsenic (As). An N-type impurity region of the photoelectric transformation portion PDR may create a P-N junction with a surrounding semiconductor substrate 2 and/or a P-type impurity region of the well region PW, thus forming s photodiode, and when light is incident, electron-hole pairs may be generated due to the P-N junction.

Active regions (e.g., the first active region 121, the second active region 123, the floating diffusion region FD, etc.) may be arranged on the first surface 2a of the semiconductor substrate 2. The active regions may be separated from each other by a device isolation layer TI arranged adjacent to the first surface 2a of the semiconductor substrate 2. The device isolation layer TI may be formed according to a Shallow Trench Isolation (STI) method. The device isolation layer TI may have a single-layer structure or a multilayered structure including at least one of a silicon oxide layer, a silicon nitride layer, and a silicon oxynitride layer. In one or more examples, the device isolation layer TI may be doped with first conductive-type impurities that are the same as the impurities doped in the semiconductor substrate 2 and may have a higher concentration than the impurities doped in the semiconductor substrate 2. The isolation pattern IL may be formed to contact the device isolation layer TI.

A first impurity region SDR1 and a second impurity region SDR2 may be formed in the second active region 123 within the semiconductor substrate 2. The first impurity region SDR1 may be shared by the first active region 121 and the second active region 123. In one or more embodiments, the first impurity region SDR1 may be a drain region of the second transistor TR2, and the second impurity region SDR2 may be a source region of the second transistor TR2. In one or more embodiments, the first impurity region SDR1 may be a source region of the second transistor TR2, and the second impurity region SDR2 may be a drain region of the second transistor TR2. The first active contact 131 may be formed to contact the first impurity region SDR1, and the third active contact 135 may be formed to contact the second impurity region SDR2. The second active contact 133 may be formed to contact an impurity region formed in the first active region 121. The second active contact 133 and the third active contact 135 may be electrically connected to each other through patterns of a wire layer (e.g. M1 or M2).

A gate insulating layer Gox may be arranged between the semiconductor substrate 2 and each of the first gate line 111, the second gate line 112, and the third gate line 113. The gate insulating layer Gox may be a layer or layers including at least one of silicon oxide, metal oxide, silicon nitride, and silicon oxynitride.

In one or more embodiments, a gate line 210 of the second transmission transistor TX2 may be a vertical-type buried gate line. For example, a portion of the gate line 210 of the second transmission transistor TX2 may be inserted into the semiconductor substrate 2. In one or more examples, the gate line 210 of the second transmission transistor TX2 may be of a planar type. The gate insulating layer Gox may be arranged between the semiconductor substrate 2 and the gate line 210 of the second transmission transistor TX2.

In the active region of the second transmission transistor TX2, the floating diffusion region FD may be arranged. The floating diffusion region FD may be doped with the first conductive-type impurities that are opposite to the second conductive-type impurities doped in the semiconductor substrate 2. For example, the floating diffusion region FD may be doped with N-type impurities, such as P or As.

On the first surface 2a, a first interlayer insulating layer ILD1 to a third interlayer insulating layer ILD3 may be sequentially stacked. Each of the first interlayer insulating layer ILD1 to the third interlayer insulating layer ILD3 may have a single-layer structure or a multilayered structure including at least one of silicon oxide, silicon nitride, silicon oxynitride, and a porous insulating material.

A first wire layer M1 may be arranged between the first interlayer insulating layer ILD1 and the second interlayer insulating layer ILD2. A second wire layer M2 may be arranged between the second interlayer insulating layer ILD2 and the third interlayer insulating layer ILD3. The active contacts (e.g., the first active contact 131, the second active contact 133, the third active contact 135, the active contact 231) and the gate contacts (e.g., the gate contacts 137 and 233) may be arranged to be connected to the first wire layer M1 by penetrating the first interlayer insulating layer ILD1. Vias penetrating the second interlayer insulating layer ILD2 may be arranged to connect the first wire layer M1 to the second wire layer M2. The number of interlayer insulating layers and the number of wire layers shown in FIGS. 6A and 6B are only examples and may vary.

A fixed charge layer 40 may be arranged on the second surface 2b of the semiconductor substrate 2 and contact the same. The fixed charge layer 40 may have negative fixed charges. The fixed charge layer 40 may include metal oxide or metal fluoride including at least one metal selected from the group consisting of hafnium (Hf), zirconium (Zr), aluminum (Al), tantalum (Ta), titanium (Ti), yttrium (Y), and lanthanoid. Hole accumulation may occur around the fixed charge layer 40, enabling a significant decrease in the generation of dark currents and white spots.

An anti-reflection layer 42 may be arranged on the fixed charge layer 40. The anti-reflection layer 42 may include, for example, silicon nitride.

Light-blocking patterns 44 and low-refractive patterns 46 may be sequentially stacked on the anti-reflection layer 42. The light-blocking pattern 44 and the low-refractive pattern 46 may each have a mesh shape in a plan view and may overlap the isolation pattern IL. The light-blocking pattern 44 and the low-refractive pattern 46 may expose the anti-reflection layer 42 above the photoelectric transformation portion PDR. The light-blocking pattern 44 may include a material, for example, Ti, which does not transmit light. The light-blocking pattern 44 and the low-refractive pattern 46 may prevent the crosstalk between adjacent pixel regions. The low-refractive pattern 46 may include an organic substance and have a refractive index that is lower than that of the color filter CF.

The color filter CF may be arranged on the anti-reflection layer 42. A microlens ML may be arranged on the color filter CF. FIGS. 6A and 6B illustrate that one microlens ML is arranged in a single pixel region, but one microlens ML may be arranged on a single pixel group, such as a pixel group including four pixel regions arranged in a 2x2 matrix.

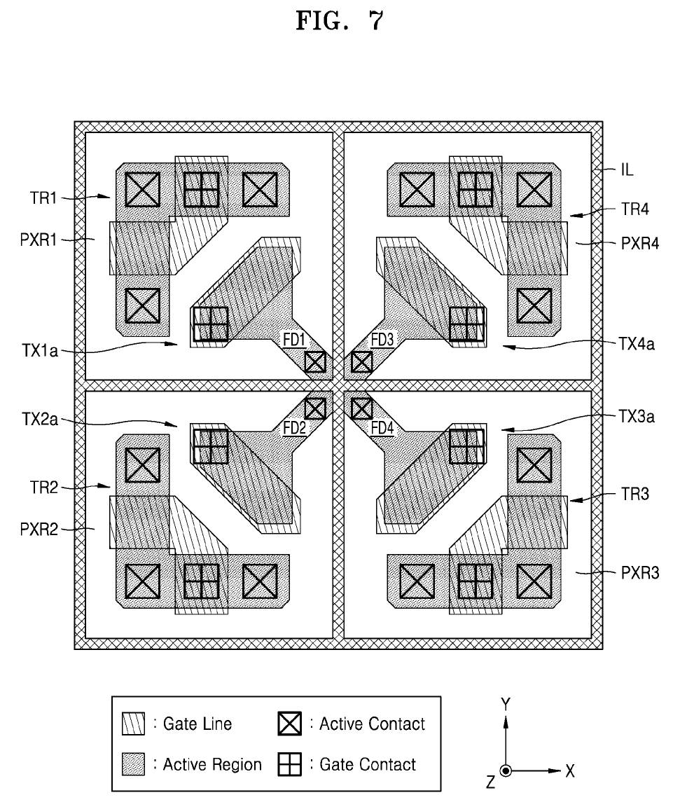

FIG. 7 is a diagram illustrating a pixel group included in an image sensor, according to one or more embodiments. In the description of FIG. 7, descriptions of the reference symbols that are the same as those shown in FIG. 3 are omitted.

Referring to FIG. 7, the pixel group may include four pixels, that is, a first pixel to a fourth pixel. The pixel group may include a first pixel region PXR1 to a fourth pixel region PXR4 which are arranged in two rows and two columns (2x2) along the X-axis direction and the Y-axis direction. A photodiode region included in each of the first pixel region PXR1 the fourth pixel region PXR4 may be separated from each other by an isolation pattern IL, and the pixel group may be distinguished from another pixel group by the isolation pattern IL.

In each of the first pixel region PXR1 to the fourth pixel region PXR4, a photoelectric conversion device may be formed, and a floating diffusion region FD, its corresponding transmission transistor among a first transmission transistor TX1a to a fourth transmission transistor TX4a, and its corresponding transistor among the first transistor TR1 to the fourth transistor TR4 may be formed. Each of the first transistor TR1 to the fourth transistor TR4 may be one of the reset transistor RX, the amplifier transistor SF, the selection transistor SX, and the storage control transistor SGX described with reference to FIGS. 2A to 2D.

The first transmission transistor TX1a to the fourth transmission transistor TX4a may each be connected to its corresponding floating diffusion region, that is, one of a first floating diffusion region FD1 to a fourth floating diffusion region FD4. Active contacts may be formed to contact the first floating diffusion region FD1 to the fourth floating diffusion region FD4, respectively. The active contacts formed to respectively contact the first floating diffusion region FD1 to the fourth floating diffusion region FD4 may be electrically connected to each other through patterns of a wire layer. Therefore, the first pixel to the fourth pixel included in the pixel group may share the first floating diffusion region FD1 to the fourth floating diffusion region FD4.

FIG. 8A is a diagram illustrating a pixel group included in an image sensor, according to one or more embodiments. FIG. 8B is a cross-sectional view of the image sensor, taken along a line Ⅲ-Ⅲ’ of FIG. 8A. In the descriptions of FIGS. 8A and 8B, descriptions regarding reference symbols that are the same as those shown in FIGS. 3, 6A, and 6B are omitted.

Referring to FIGS. 8A and 8B, the pixel group may include four pixels, that is, a first pixel to a fourth pixel. The pixel group may include a first pixel region PXR1 to a fourth pixel region PXR4 which are arranged in two rows and two columns (2x2). A photodiode region included in each of the first pixel region PXR1 to the fourth pixel region PXR4 may be separated from each other by an isolation pattern IL, and the pixel group may be distinguished from another pixel group by the isolation pattern IL.

In each of the first pixel region PXR1 to the fourth pixel region PXR4, a photoelectric conversion device may be formed, and a floating diffusion region FD, its corresponding transmission transistor among the first transmission transistor TX1 to the fourth transmission transistor TX4, and its corresponding transistor among a first transistor TR1b to a fourth transistor TR4b may be formed. Each of the first transistor TR1b to the fourth transistor TR4b may be one of the reset transistor RX, the amplifier transistor SF, the selection transistor SX, and the storage control transistor SGX described with reference to FIGS. 2A to 2D.

The first transistor TR1b, the third transistor TR3b, and the fourth transistor TR4b may each include a first active region extending in the first direction Y and a second active region extending in the second direction X. At least one of the first transistor TR1b, the third transistor TR3b, and the fourth transistor TR4b may include a gate line 110_3 extending in a third direction intersecting the first direction Y and the second direction X, and a gate contact 137_3 may be formed to contact the gate line 110_3. In this case, the third direction may be parallel to the main surface of the semiconductor substrate 2 and be an orthogonal direction between the first direction Y and the second direction X. FIG. 8A illustrates that all of the first transistor TR1b, the third transistor TR3b, and the fourth transistor TR4b include the gate lines 110_3 extending in the third direction, but one or more embodiments are not limited thereto. Some of the first transistor TR1b, the third transistor TR3b, and the fourth transistor TR4b may include the gate structure (110 of FIG. 4) having the same shape as the second transistor TR2.

In each active region of the first transistor TR1b, the third transistor TR3b, and the fourth transistor TR4b which include the gate lines 110_3 extending in the third direction, an active contact contacting a source region and an active contact contacting a drain region, that is, two active contacts, may be formed.

In one or more embodiments, the gate line 210 of the second transmission transistor TX2 and the gate line 210_3 of the fourth transmission transistor TX4 may be vertical-type buried gate lines. In one or more examples, the gate line 210 of the second transmission transistor TX2 and the gate line 210_3 of the fourth transmission transistor TX4 may each be of a planar type. Gate insulating layers Gox may be arranged between the semiconductor substrate 2 and the gate line 210 of the second transmission transistor TX2 and between the semiconductor substrate 2 and the gate line 210_3 of the fourth transmission transistor TX4. The gate contacts 233 and 233_3 connected to the first wire layer M1 may be arranged on the gate line 210 of the second transmission transistor TX2 and the gate line 210_3 of the fourth transmission transistor TX4, respectively.

The color filter CF may be arranged on the anti-reflection layer 42, and a microlens ML’ may be arranged on the color filter CF. A single microlens ML’ may be arranged on one pixel group. However, one or more embodiments are not limited thereto, and a single microlens ML’ may be arranged in one pixel region.

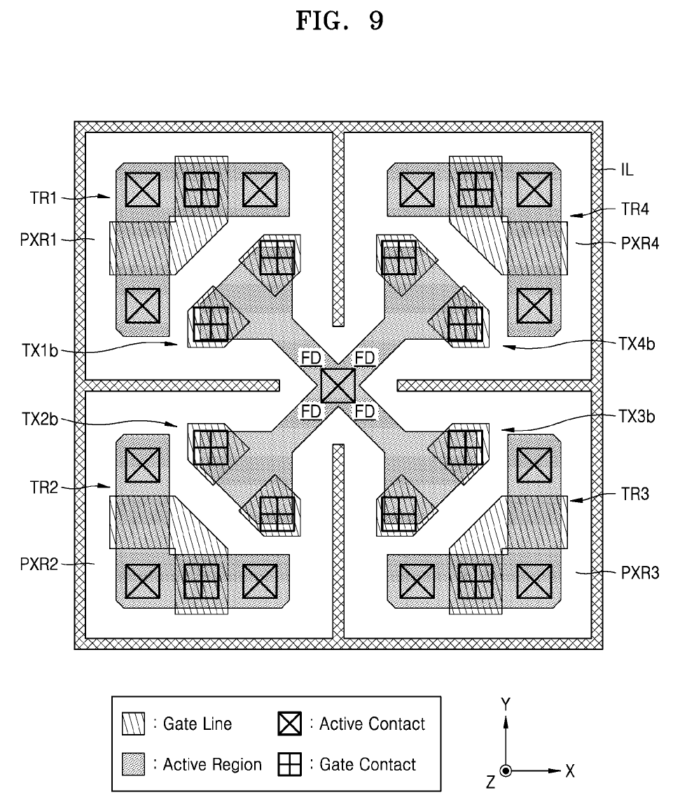

FIG. 9 is a diagram illustrating a pixel group included in an image sensor, according to one or more embodiments. In the description of FIG. 9, descriptions regarding the reference symbols that are the same as those shown in FIG. 3 are omitted.

Referring to FIG. 9, the pixel group may include four pixels, that is, a first pixel to a fourth pixel. The pixel group may include a first pixel region PXR1 to a fourth pixel region PXR4 which are arranged in two rows and two columns (2x2) along the X-axis direction and the Y-axis direction. A photodiode region included in each of the first pixel region PXR1 to the fourth pixel region PXR4 may be separated from each other by an isolation pattern IL, and the pixel group may be distinguished from another pixel group by the isolation pattern IL.

In each of the first pixel region PXR1 to the fourth pixel region PXR4, a photoelectric conversion device may be formed, and a floating diffusion region FD, its corresponding transmission transistor among a first transmission transistor TX1b to a fourth transmission transistor TX4b, and its corresponding transistor among the first transistor TR1 to the fourth transistor TR4 may be formed. Each of the first transistor TR1 to the fourth transistor TR4 may be one of the reset transistor RX, the amplifier transistor SF, the selection transistor SX, and the storage control transistor SGX described with reference to FIGS. 2A to 2D.

Compared to the first transmission transistor TX1 to the fourth transmission transistor TX4 of FIG. 3, the first transmission transistor TX1b to the fourth transmission transistor TX4b may include gate lines including first gate patterns and second gate patterns that are separated from each other. The gate contacts may be arranged to contact the first gate patterns and the second gate patterns, and the first gate patterns may be electrically connected to the second gate patterns through the gate contacts and the patterns of the wire layer.

Each of the first gate pattern and the second gate pattern may be of a buried type. As a recess is formed by etching the semiconductor substrate and a gate insulating pattern and a buried gate pattern are formed in the recess, the first gate pattern and the second gate pattern of each of the first transmission transistor TX1b to the fourth transmission transistor TX4b may be formed.

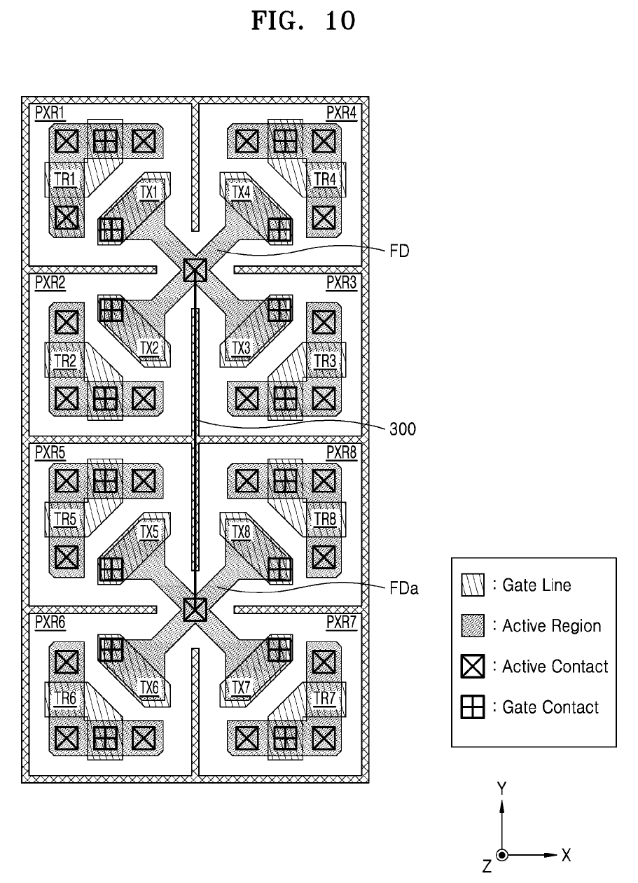

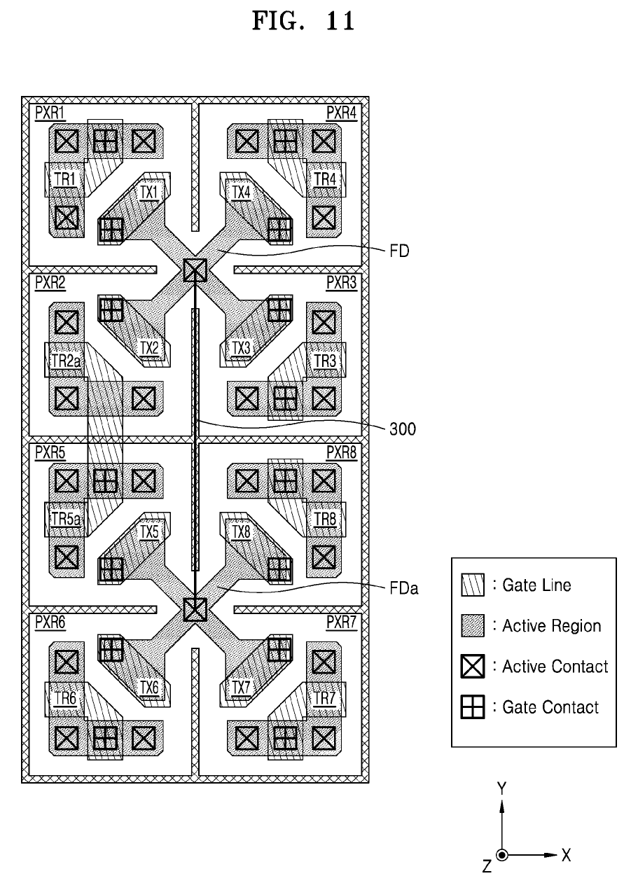

FIGS. 10 and 11 are diagrams illustrating pixel groups included in an image sensor, according to one or more embodiments. In the descriptions of FIGS. 10 and 11, the descriptions regarding the reference symbols that are the same as those shown in FIG. 3 are omitted.

Referring to FIG. 10, the pixel group may include eight pixels, that is, a first pixel to an eighth pixel.. The pixel group may include a first pixel region PXR1 to an eighth pixel region PXR8 respectively corresponding to the first pixel to the eighth pixel, which are arranged in four rows and two columns (4x2) along the X-axis direction and the Y-axis direction. A photodiode region included in each of the first pixel region PXR1 to the eighth pixel region PXR8 may be separated from each other by the isolation pattern IL, and the pixel group may be distinguished from another pixel group by the isolation pattern IL.

In each of the first pixel region PXR1 to the eighth pixel region PXR8, a photoelectric conversion device may be formed, and a floating diffusion region FD, its corresponding transmission transistor among the first transmission transistor TX1 to the eighth transmission transistor TX8, and its corresponding transistor among the first transistor TR1 to the eighth transistor TR8 may be formed. The first transistor TR1 to the eighth transistor TR8 may include the first amplifier transistor SF1 to the k^{th} amplifier transistor SFk described with reference to FIG. 2B, the reset transistor RX and the storage control transistor SGX described with reference to FIG. 2C, and the first selection transistor SX1 to the j^{th} selection transistor SXj described with reference to FIG. 2D. However, one or more embodiments are not limited thereto, and at least one of the first transistor TR1 to the eighth transistor TR8 may be a dummy transistor.

The fifth pixel region PXR5 to the eighth pixel region PXR8 may have the same structures as the first pixel region PXR1 to the fourth pixel region PXR4. The descriptions regarding the first pixel region PXR1 to the fourth pixel region PXR4 of FIG. 3 may be identically applied to the first pixel region PXR1 to the fourth pixel region PXR4 and also to the fifth pixel region PXR5 to the eighth pixel region PXR8.

The first pixel region PXR1 to the fourth pixel region PXR4 may share the floating diffusion region FD, and the fifth pixel region PXR5 to the eighth pixel region PXR8 may share a floating diffusion region FDa. The floating diffusion regions FD and FDa included in the pixel group may be electrically connected to each other through a pattern 300 of a wire layer and active contacts, and the first pixel to the eighth pixel included in the pixel group may share the floating diffusion regions FD and FDa. However, as described above with reference to FIG. 7, an individual floating diffusion region may be formed in each of the first pixel region PXR1 to the eighth pixel region PXR8, and the floating diffusion regions, which are individually formed, may be electrically connected to each other through the active contacts and the patterns of the wire layer.

In addition, FIG. 10 illustrates that the first transistor TR1 to the eighth transistor TR8 each include a gate line structure including a first gate line, a second gate line, and a third gate line, but one or more embodiments are not limited thereto. For example, as described with reference to FIG. 8A, the second transistor TR2 and the fifth transistor TR5, which are some of the first transistor TR1 to the eighth transistor TR8, may include the gate line structures, and the first transistor TR1, the third transistor TR3, the fourth transistor TR4, and the sixth transistor TR6 to the eighth transistor TR8, which are the others, may each include a gate line extending in the third direction intersecting the first direction Y and the second direction X.

In addition, FIG. 10 illustrates that the gate line of each of the first transmission transistor TX1 to the eighth transmission transistor TX8 has a single pattern, but one or more embodiments are not limited thereto. As described with reference to FIG. 9, the gate lines of the first transmission transistor TX1 to the eighth transmission transistor TX8 may be formed to include a plurality of gate patterns that are electrically connected to each other through the wire layer, respectively.

Referring to FIG. 11, in each of the first pixel region PXR1 to the eighth pixel region PXR8, a photoelectric conversion device may be formed, and a floating diffusion region FD, its corresponding transmission transistor among the first transmission transistor TX1 to the eighth transmission transistor TX8, and its corresponding transistor among the first transistor TR1, the second transistor TR2a, the third transistor TR3, the fourth transistor TR4, the fifth transistor TR5a, and the sixth transistor TR6 to the eighth transistor TR8 may be formed. The first transistor TR1, the second transistor TR2a, the third transistor TR3, the fourth transistor TR4, the fifth transistor TR5a, and the sixth transistor TR6 to the eighth transistor TR8 may include the first amplifier transistor SF1 to the k^{th} amplifier transistor SFk described with reference to FIG. 2B, the reset transistor RX and the storage control transistor SGX described with reference to FIG. 2C, and the first selection transistor SX1 to the j^{th} selection transistor SXj described with reference to FIG. 2D. However, one or more embodiments are not limited thereto, and at least one of the first transistor TR1, the second transistor TR2a, the third transistor TR3, the fourth transistor TR4, the fifth transistor TR5a, and the sixth transistor TR6 to the eighth transistor TR8 may be a dummy transistor.

The second transistor TR2a and the fifth transistor TR5a may be formed such that the gate structures thereof may contact and be connected to each other. For example, the second gate line of the second transistor TR2a and the second gate line of the fifth transistor TR5a may extend in the first direction (the Y-axis direction) and be connected to each other. The second transistor TR2a and the fifth transistor TR5a may operate as a single transistor and may be, for example, the first amplifier transistor SF1 to the k^{th} amplifier transistor SFk described with reference to FIG. 2B. Because the gate structure of the second transistor TR2a is connected to that of the fifth transistor TR5a, a single gate contact may be formed to contact the gate structure of the second transistor TR2a and the gate structure of the fifth transistor TR5a.

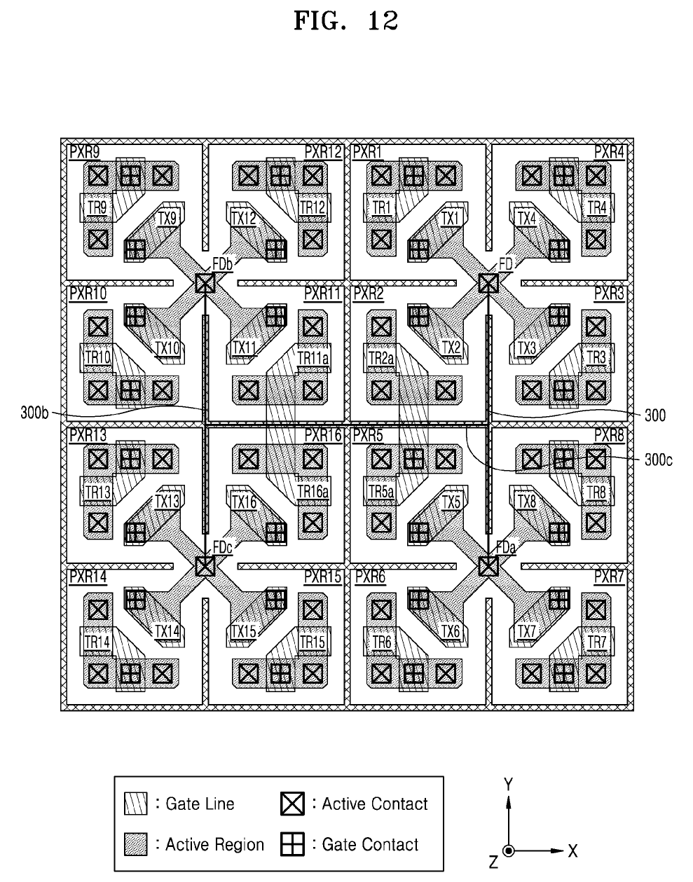

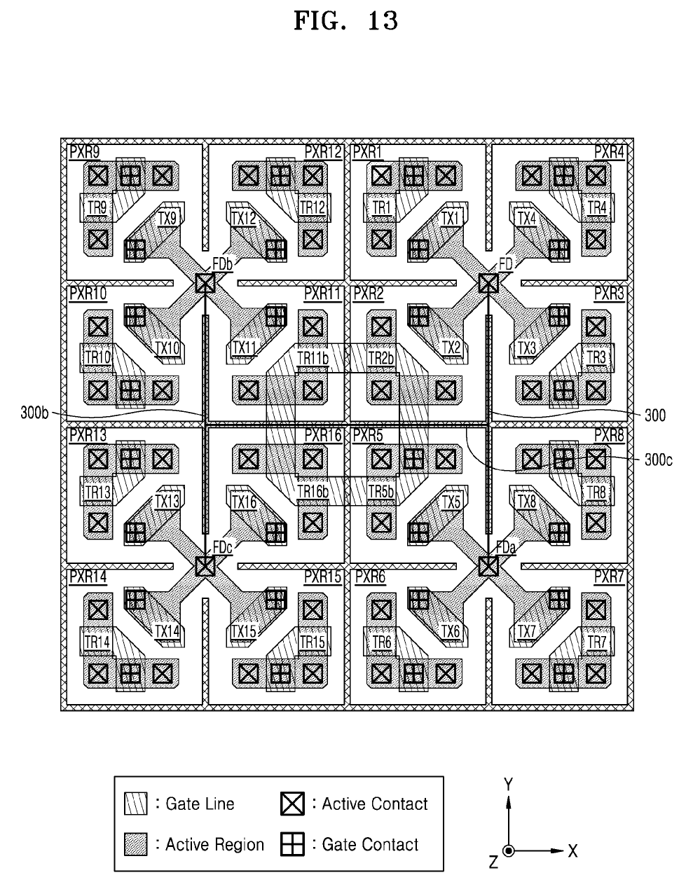

FIGS. 12 and 13 are diagrams illustrating pixel groups included in an image sensor, according to one or more embodiments. In the descriptions of FIGS. 12 and 13, the descriptions regarding the reference symbols that are the same as those shown in FIG. 3 are omitted.

Referring to FIG. 12, the pixel group may include 16 pixels, that is, a first pixel to a 16^{th} pixel. The pixel group may include a first pixel region PXR1 to a 16^{th} pixel region PXR16 respectively corresponding to the first pixel to the 16^{th} pixel, which are arranged in four rows and four columns (4x4) along the X-axis direction and the Y-axis direction. A photodiode region included in each of the first pixel region PXR1 to the 16^{th} pixel region PXR16 may be separated from each other by the isolation pattern IL, and the pixel group may be distinguished from another pixel group by the isolation pattern IL.

In each of the first pixel region PXR1 to the 16^{th} pixel region PXR16, a photoelectric conversion device may be formed, and a floating diffusion region FD, its corresponding transmission transistor among the first transmission transistor TX1 to the 16^{th} transmission transistor TX16, and its corresponding transistor among the first transistor TR1, the second transistor TR2a, the third transistor TR3, the fourth transistor TR4, the fifth transistor TR5a, the sixth transistor TR6 to the tenth transistor TR10, an 11^{th} transistor TR11a, a 12^{th} transistor TR12 to a 15^{th} transistor TR15, and a 16^{th} transistor TR16a may be formed.

The first transistor TR1, the second transistor TR2a, the third transistor TR3, the fourth transistor TR4, the fifth transistor TR5a, the sixth transistor TR6 to the tenth transistor TR10, the 11^{th} transistor TR11a, the 12^{th} transistor TR12 to the 15^{th} transistor TR15, and the 16^{th} transistor TR16a may each be one of the reset transistor RX, the amplifier transistor SF, the selection transistor SX, and the storage control transistor SGX described with reference to FIGS. 2A to 2D. For example, the first transistor TR1, the second transistor TR2a, the third transistor TR3, the fourth transistor TR4, the fifth transistor TR5a, the sixth transistor TR6 to the tenth transistor TR10, the 11^{th} transistor TR11a, the 12^{th} transistor TR12 to the 15^{th} transistor TR15, and the 16^{th} transistor TR16a may include the first amplifier transistor SF1 to the k^{th} amplifier transistor SFk described with reference to FIG. 2B, the reset transistor RX and the storage control transistor SGX described with reference to FIG. 2C, and the first selection transistor SX1 to the j^{th} selection transistor SXj described with reference to FIG. 2D. However, one or more embodiments are not limited thereto, and at least one of the first transistor TR1, the second transistor TR2a, the third transistor TR3, the fourth transistor TR4, the fifth transistor TR5a, the sixth transistor TR6 to the tenth transistor TR10, the 11^{th} transistor TR11a, the 12^{th} transistor TR12 to the 15^{th} transistor TR15, and the 16^{th} transistor TR16a may be a dummy transistor.

The second transistor TR2a and the fifth transistor TR5a may be formed such that the gate structures thereof may contact and be connected to each other. For example, the second gate line of the second transistor TR2a and the second gate line of the fifth transistor TR5a may extend in the first direction (the Y-axis direction) and be connected to each other. Because the gate structure of the second transistor TR2a is connected to that of the fifth transistor TR5a, a single gate contact may be formed to contact the gate structure of the second transistor TR2a and the gate structure of the fifth transistor TR5a.

The 11^{th} transistor TR11a and the 16^{th} transistor TR16a may be formed such that the gate structures thereof may contact and be connected to each other. For example, the second gate line of the 11^{th} transistor TR11a and the second gate line of the 16^{th} transistor TR16a may extend in the first direction (the Y-axis direction) and be connected to each other. Because the gate structure of the 11^{th} transistor TR11a) is connected to that of the 16^{th} transistor TR16a, a single gate contact may be formed to contact the gate structure of the 11th transistor T11a and the gate structure of the 16th transistor TR16a.

In one or more embodiments, the gate structures of the second transistor TR2a and the fifth transistor TR5a may be electrically connected to the gate structures of the 11^{th} transistor TR11a and the 16^{th} transistor TR16a through the gate contacts and the patterns of the wire layer. The second transistor TR2a, the fifth transistor TR5a, the 11^{th} transistor TR11a, and the 16^{th} transistor TR16a may operate as a single transistor, and for example, the second transistor TR2a, the fifth transistor TR5a, the 11^{th} transistor TR11a, and the 16^{th} transistor TR16a may be the first amplifier transistor SF1 to the k^{th} amplifier transistor SFk described with reference to FIG. 2B. However, one or more embodiments are not limited thereto, and the gate structures of the second transistor TR2a and the fifth transistor TR5a may be electrically separated from the gate structures of the 11^{th} transistor TR11a and the 16^{th} transistor TR16a.

The fifth pixel region PXR5 to the eighth pixel region PXR8 may have the same structure as the first pixel region PXR1 to the fourth pixel region PXR4, the ninth pixel region PXR9 to the 12^{th} pixel region PXR12 may have the same structure as the first pixel region PXR1 to the fourth pixel region PXR4, and the 13^{th} pixel region PXR13 to the 16^{th} pixel region PXR16 may have the same structure as the first pixel region PXR1 to the fourth pixel region PXR4. The descriptions regarding the first pixel region PXR1 to the fourth pixel region PXR4 of FIG. 3 may be identically applied to the first pixel region PXR1 to the fourth pixel region PXR4.

The first pixel region PXR1 to the fourth pixel region PXR4 may share the floating diffusion region FD, and the fifth pixel region PXR5 to the eighth pixel region PXR8 may share a floating diffusion region FDa. The ninth pixel region PXR9 to the 12^{th} pixel region PXR12 may share a floating diffusion region FDb, and the 13^{th} pixel region PXR13 to the 16^{th} pixel region PXR16 may share a floating diffusion region FDc. The floating diffusion regions FD, FDa, FDb, and FDc included in a single pixel group may be electrically connected to each other through patterns 300, 300b, and 300c of a wire layer and active contacts, and a first pixel to a 16^{th} pixel included in the pixel group may share the floating diffusion regions FD, FDa, FDb, and FDc. However, as described with reference to FIG. 7, an individual floating diffusion region may be formed in each of the first pixel region PXR1 to the 16^{th} pixel region PXR16, and the floating diffusion regions, which are individually formed, may be electrically connected to each other through the active contacts and the patterns of the wire layer.

In addition, FIG. 12 illustrates that all of the first transistor TR1, the second transistor TR2a, the third transistor TR3, the fourth transistor TR4, the fifth transistor TR5a, the sixth transistor TR6 to the 10^{th} transistor TR10, the 11^{th} transistor TR11a, the 12^{th} transistor TR12 to the 15^{th} transistor TR15, and the 16^{th} transistor TR16a include gate line structures each including a first gate line, a second gate line, and a third gate line, but one or more embodiments are not limited thereto. For example, as described with reference to FIG. 8A, the second transistor TR2a, the fifth transistor TR5a, the 11^{th} transistor TR11a, and the 16^{th} transistor TR16a, which are some of the first transistor TR1, the second transistor TR2a, the third transistor TR3, the fourth transistor TR4, the fifth transistor TR5a, the sixth transistor TR6 to the 10^{th} transistor TR10, the 11^{th} transistor TR11a, the 12^{th} transistor TR12 to the 15^{th} transistor TR15, and the 16^{th} transistor TR16a, may include the gate line structures, and the others thereof may include gate lines extending in the third direction intersecting the first direction Y and the second direction X.

In addition, FIG. 12 illustrates that the gate line of each of the first transmission transistor TX1 to the 16^{th} transmission transistor TX16 has a single pattern, but one or more embodiments are not limited thereto. As described with reference to FIG. 9, the gate line of each of the first transmission transistor TX1 to the 16^{th} transmission transistor TX16 may be formed to include a plurality of gate patterns that are electrically connected to each other through the wire layer.

Referring to FIG. 13, in each of the first pixel region PXR1 to the 16^{th} pixel region PXR16, a photoelectric conversion device may be formed, and a floating diffusion region FD, its corresponding transmission transistor among the first transmission transistor TX1 to the 16^{th} transmission transistor TX16, and its corresponding transistor among the first transistor TR1, the second transistor TR2b, the third transistor TR3, the fourth transistor TR4, the fifth transistor TR5b, the sixth transistor TR6 to the 10^{th} transistor TR10, the 11^{th} transistor TR11b, the 12^{th} transistor TR12 to the 15^{th} transistor TR15, and the 16^{th} transistor TR16b may be formed. The first transistor TR1, the second transistor TR2b, the third transistor TR3, the fourth transistor TR4, the fifth transistor TR5b, the sixth transistor TR6 to the 10^{th} transistor TR10, the 11^{th} transistor TR11b, the 12^{th} transistor TR12 to the 15^{th} transistor TR15, and the 16^{th} transistor TR16b may include the first amplifier transistor SF1 to the k^{th} amplifier transistor SFk described with reference to FIG. 2B, the reset transistor RX and the storage control transistor SGX described with reference to FIG. 2C, and the first selection transistor SX1 to the j^{th} selection transistor SXj described with reference to FIG. 2D. However, one or more embodiments are not limited thereto, and at least one of the first transistor TR1, the second transistor TR2b, the third transistor TR3, the fourth transistor TR4, the fifth transistor TR5b, the sixth transistor TR6 to the 10^{th} transistor TR10, the 11^{th} transistor TR11b, the 12^{th} transistor TR12 to the 15^{th} transistor TR15, and the 16^{th} transistor TR16b may be a dummy transistor.

For example, the second transistor TR2b, the fifth transistor TR5b, the 11^{th} transistor TR11b, and the 16^{th} transistor TR16b may be the first amplifier transistor SF1 to the k^{th} amplifier transistor SFk described with reference to FIG. 2B. The gate structures of the second transistor TR2b, the fifth transistor TR5b, the 11^{th} transistor TR11b, and the 16^{th} transistor TR16b may be connected to each other. For example, second gate lines of the second transistor TR2b and the fifth transistor TR5b may extend in the first direction (the Y-axis direction) and be connected to each other, second gate lines of the 11^{th} transistor TR11b and the 16^{th} transistor TR16b may extend in the first direction (the Y-axis direction) and be connected to each other, first gate lines of the second transistor TR2b and the 11^{th} transistor TR11b may extend in the second direction (the X-axis direction) and be connected to each other, first gate lines of the fifth transistor TR5b and the 16^{th} transistor TR16b may extend in the second direction (the X-axis direction) and be connected to each other.

The second transistor TR2b, the fifth transistor TR5b, the 11^{th} transistor TR11b, and the 16^{th} transistor TR16b may operate as a single amplifier transistor. Because the gate structures of the second transistor TR2b, the fifth transistor TR5b, the 11^{th} transistor TR11b, and the 16^{th} transistor TR16b are connected to each other, one gate contact may be formed to contact the gate structures of the second transistor TR2b, the fifth transistor TR5b, the 11^{th} transistor TR11b, and the 16^{th} transistor TR16b.

While the embodiments of the present disclosure have been particularly shown and described with reference to embodiments thereof, it will be understood that various changes in form and details may be made therein without departing from the spirit and scope of the following claims.

What is claimed is:

1. An image sensor comprising:
a first pixel region; and
a second pixel region,
wherein the first pixel region comprises:
a first active region on a semiconductor substrate and extending in a first direction;
a second active region on the semiconductor substrate, contacting the first active region, and extending in a second direction that is different from the first direction; and
a first transistor that comprises a first gate structure, the first active region, and the second active region,
wherein the first gate structure comprises a first gate line on the first active region, a second gate line on the second active region, and a third gate line connecting the first gate line to the second gate line, and
wherein at least a portion of the third gate line is arranged to extend over a device isolation layer separating the first active region and the second active region from other active regions.

2. The image sensor of claim 1, wherein
each of the first active region and the second active region comprises:
a photoelectric conversion device on the semiconductor substrate,
a floating diffusion region in which photocharges generated by the photoelectric conversion device accumulate, and
a transmission transistor configured to transmit the photocharges generated by the photoelectric conversion device to the floating diffusion region.

3. The image sensor of claim 2, wherein the first transistor comprises an amplifier transistor configured to amplify a voltage at the floating diffusion region of the first pixel region and output the voltage as a pixel signal.

4. The image sensor of claim 2, wherein the floating diffusion region of the first pixel region contacts the floating diffusion region of the second pixel region.

5. The image sensor of claim 2, wherein
the floating diffusion region of the first pixel region is separated from the floating diffusion region of the second pixel region, and
the floating diffusion region of the first pixel region is connected to the floating diffusion region of the second pixel region through a pattern of a wire layer.

6. The image sensor of claim 1, wherein the first pixel region further comprises a gate contact that contacts one of the first gate line and the second gate line.

7. The image sensor of claim 1, wherein
the first pixel region further comprises:
a first active contact that contacts the first active region,
a second active contact that contacts the second active region, and
a third active contact that contacts the first active region and the second active region.

8. The image sensor of claim 1, wherein a first channel of the first transistor is on the first active region and a second channel of the first transistor is on the second active region.

9. The image sensor of claim 1, wherein
the second pixel region comprises:
a third active region extending in the first direction,
a fourth active region extending in the second direction, and
a second transistor that comprises a second gate structure, the third active region, and the fourth active region, and
the second gate structure contacts the first gate structure.

10. An image sensor comprising:
a first pixel region; and
a second pixel region,
wherein the first pixel region comprises:
a first active region and a second active region on a semiconductor substrate;
a first active contact, a second active contact, and a third active contact each of which contacts at least one of the first active region and the second active region,
a first transistor that comprises a first gate structure, the first active region, and the second active region, and
a device isolation layer on the semiconductor substrate and separating the first active region and the second active region from other active regions,
wherein the first gate structure comprises a first gate line on the first active region, a second gate line on the second active region, and a third gate line connecting the first gate line to the second gate line, and
wherein at least a portion of the third gate line overlaps the device isolation layer in a first direction of the semiconductor substrate.

11. The image sensor of claim 10, wherein
the second pixel region comprises:
a third active region and a fourth active region, and
a second transistor comprising a gate line, the third active region, and the fourth active region, and
wherein the gate line of the second transistor extends in a second direction that intersects an extension direction of the third active region and an extension direction of the fourth active region,
wherein the second direction is different than the first direction.

12. The image sensor of claim 10, wherein
the second pixel region comprises:
a third active region and a fourth active region, and
a second transistor that comprises a second gate structure, the third active region, and the fourth active region, and
wherein the second gate structure contacts the first gate structure.

13. The image sensor of claim 10, wherein
each of the first active region and the second active region comprises:
a photoelectric conversion device on the semiconductor substrate,
a floating diffusion region in which photocharges generated by the photoelectric conversion device accumulate, and
a transmission transistor configured to transmit the photocharges generated by a photoelectric transformation element to the floating diffusion region.

14. The image sensor of claim 13, wherein
the first transistor comprises one of a reset transistor configured to reset the floating diffusion region of the first pixel region, an amplifier transistor configured to amplify a voltage at the floating diffusion region of the first pixel region, and a selection transistor connected to the amplifier transistor and configured to output a pixel signal.

15. The image sensor of claim 13, wherein the floating diffusion region of the first pixel region is connected to the floating diffusion region of the second pixel region.

16. The image sensor of claim 10, wherein the first pixel region further comprises a gate contact that contacts one of the first gate line and the second gate line.

17. An image sensor:
comprising a pixel region,
wherein the pixel region comprises:
a first active region and a second active region on a semiconductor substrate, and
a transistor comprising a gate structure, the first active region, and the second active region,
wherein the gate structure comprises a first gate line on the first active region, a second gate line on the second active region, and a third gate line connecting the first gate line to the second gate line, and
wherein a first channel of the transistor is on the first active region, and a second channel of the transistor is on the second active region.

18. The image sensor of claim 17, further comprising:
a device isolation layer on the semiconductor substrate and separating the first active region and the second active region from other active regions,
wherein the first gate line is arranged to cross the first active region, and the second gate line is arranged to cross the second active region, and
wherein the third gate line is arranged to overlap the device isolation layer, in a first direction of the semiconductor substrate.

19. The image sensor of claim 17, wherein
the pixel region further comprises:
a first active contact that contacts the first active region,
a second active contact that contacts the second active region, and
a third active contact that contacts the first active region and the second active region.

20. The image sensor of claim 17, wherein the pixel region further comprises a gate contact that contacts one of the first gate line and the second gate line.
